(19) United States
(12) Patent Application Publication
(10) Pub. No.: US 2001/0025997 A1
(43) Pub. Date: Oct. 4, 2001

(54) Semiconductor integrated circuit device and fabrication method

(75) Inventor: Hideaki Onishi, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/803,904

(22) Filed: Mar. 13, 2001

(30) Foreign Application Priority Data
Mar. 17, 2000 (JP) 2000-076617

(51) Int. Cl. H01L 21/8238; H01L 21/336; H01L 29/76; H01L 29/94; H01L 31/062; H01L 31/113; H01L 31/119

(52) U.S. Cl. 257/402; 438/217; 438/289

(57) ABSTRACT

The threshold voltages of transistors are set by controlling the amount of overlap in the direction of channel length between a channel region and a source region and the amount of overlap in the direction of channel length between the channel region and a drain region, whereby, in a semiconductor integrated circuit device in which transistors having different threshold voltages or different channel widths are mounted together, the ion injection conditions for the channel regions can be shared, thereby reducing the number of masks and the number of processing steps.

### BACKGROUND OF THE INVENTION

1. Field of the Invention

The present invention relates to a semiconductor integrated circuit device in which a plurality of types of transistors having differing performance are mounted together, and to a method of fabricating such a device.

2. Description of the Related Art

The trend in semiconductor integrated circuit devices of recent years is toward System-On-Chip architecture which, instead of a configuration having only the function of, for example, a CPU, logic circuits, or memory, constitutes a system by mounting these different components on a single chip.

Because different performance is demanded for each function, a plurality of types of transistors having, for example, different threshold voltages Vth, are mounted together in this type of semiconductor integrated circuit device. Generally, the threshold voltage Vth of a transistor is set to a desired value by varying the concentration of impurity in the channel region of the transistor and formed by procedures such as those shown in FIGS. 1 and 2. A case is described below in which an n-channel FET of MOS (Metal Oxide Semiconductor) construction is used as the transistor.

In a method of fabricating a semiconductor integrated circuit device of the prior art, the surface of p-type semiconductor substrate 110 having a low impurity concentration (less than 1×10¹⁶ atms/cm³) is first subjected to thermal oxidation to grow a thermal oxide film composed of silicon dioxide (SiO₂) and having a thickness of 5 nm, following which a silicon nitride film (Si₃N₄) having a thickness of 150 nm is grown over this film by a CVD (Chemical Vapor Deposition) method. A photoresist is then formed on the silicon nitride film, and this photoresist is then patterned using photolithography to form element isolation regions for isolating each transistor.

The silicon nitride film and thermal oxide film in the openings of the photoresist are then each removed by dry etching, and moreover, the surface around p-type semiconductor substrate 110 is removed by etching to form trenches of a depth of, for example, 200-400 nm.

The photoresist on the silicon nitride film is then removed, and an inner-wall oxide film made up of silicon dioxide (SiO₂) and having a thickness of 10-40 nm is grown on the bottom and side surfaces of the trenches by a thermal oxidation method.

Next, a plasma oxide film composed of silicon dioxide (SiO₂) is buried inside the trench using an HDP (High-Density Plasma)-CVD method, following which the upper surface of the plasma oxide film is leveled by CMP (Chemical Mechanical Polishing) to expose the silicon nitride film. The silicon nitride film and thermal oxide film on the p-type semiconductor substrate 110 are then removed by wet etching, thereby forming element isolation region 120 (FIG. 1(a)).

First photoresist 121a is next formed on p-type semiconductor substrate 110, following which first photoresist 121a is patterned using photolithography such that only the formation area of high-threshold transistors, which are transistors having a high threshold voltage Vth, has open portions.

Next, boron (B) is injected through the open portions of first photoresist 121a and into the surface of p-type semiconductor substrate 110 under the conditions of, for example, 10-40 keV and 1-3×10¹³ atms/cm², thereby forming high-concentration channel region 111a, which is to be the channel of high-threshold transistor (FIG. 1(b)).

After next removing first photoresist 121a on p-type semiconductor substrate 110, second photoresist 121b is formed, following which second photoresist 121b is patterned using photolithography such that only the formation region of low-threshold transistors, which are transistors having a low threshold voltage, has an open portion.

Boron (B) is then injected through the open portions of second photoresist 121b and into the surface of p-type semiconductor substrate 110 under the conditions of, for example, 10-40 keV and 2×10¹²-1.2×10¹³ atms/cm², thereby forming low-concentration channel region 111b which is to become the channel of a low-threshold transistor (FIG. 1(c)).

Next, after removing second photoresist 121b on p-type semiconductor substrate 110, the surface of p-type semiconductor substrate 110 is subjected to thermal oxidation at a temperature of 700° C.-1000° C. to form gate oxide film 114 that is composed of silicon dioxide (SiO₂) and having a thickness of approximately 3 nm, following which a polysilicon film that is to become a gate electrode and having a thickness of approximately 150 nm (less than 300 nm) is formed by CVD.

A photoresist is then formed on the polysilicon film, following which the photoresist is patterned using photolithography for forming the gate electrode and the polysilicon film at the open portion of the photoresist is removed by dry etching, thereby forming gate electrode 113.

Using gate electrode 113 as a mask, arsenic (As) is injected into p-type semiconductor substrate 110 under the conditions of, for example, 2 keV (5 keV or less) and 2×10¹⁴-2×10¹⁵ atms/cm² to form SD extension region 122 (FIG. 2(d)).

Next, a silicon oxide film, a silicon nitride film, or a dielectric film in which these two films are laminated and having a thickness of 200-400 nm is deposited on p-type semiconductor substrate 110 and gate electrode 113 by CVD, following which etch-back is carried out by dry etching to form side walls 115 on the side surfaces of gate electrode 113.

Using gate electrode 113 and side walls 115 as a mask, arsenic (As) is injected into p-type semiconductor substrate 110 under the conditions of, for example, 20-40 keV and 2×10¹⁵-1×10¹⁶ atms/cm² to form source region and drain region 112 (hereinbelow referred to as “source-drain region”) (FIG. 2(e)).

Finally, an RTA (Rapid Thermal Anneal) process is carried out under the conditions of 900° C.-1100° C. and 10 sec (60 seconds or less) to activate each of the dopants of the channel regions and source-drain regions 112, thereby completing each of low-threshold transistor 101 and high-threshold transistor 102 (FIG. 2(f)). The source and drain are subsequently wired using, for example, silicide by a known method.

As described in the foregoing explanation, in a semiconductor integrated circuit device in which a plurality of types of transistors having different threshold voltages are mounted together, separate ion injection processes are necessary to vary the impurity concentrations of the channel regions of each of the high-threshold transistors having a high threshold voltage and the low-threshold transistors having a low threshold voltage. In particular, the ion injection processes increase in accordance with the increase in the varieties of transistors. Since the number of photomasks for patterning photoresists and the number of processes are greater than for a general-purpose semiconductor integrated circuit device having only one function, there has been the problem that TAT (turn-around time) is lengthy and costs are increased.

As an example of a semiconductor integrated circuit device in which a plurality of types of transistors having differing threshold voltages are mounted together, there is a construction in which, for example, a high-speed logic unit and a logic unit having lower speed are mounted together on a single chip, the high-speed logic unit being activated only when a prompt is applied from the outside, and the low-speed logic unit being continuously operated as a circuit for detecting this prompt. In concrete terms, in battery-driven electronic device such as a portable telephone, only the low-speed logic unit is operated during standby mode so as to realize low power consumption, and a high-speed logic unit such as an arithmetic processor is operated in accordance with a prompt that is applied from the outside. In this case, “high-speed” and “low-speed” signify relative operating speeds rather than absolute operating speeds.

In this type of semiconductor integrated circuit device, the threshold voltage of transistors of the high-speed logic unit is set lower than that of the transistors of the low-speed logic unit. In a case in which the channel lengths and channel widths of these transistors are the same, the impurity concentration of the channel regions is varied by individual ion injection processes as described hereinabove to adjust the threshold values of the transistors for low-speed logic and transistors for high-speed logic, and costs therefore increase.

As another example of a semiconductor integrated circuit device in which a plurality of types of transistors having different threshold voltages are mounted together, there is a construction in which the logic devices of memory and CPU are mounted together. The area per cell must be limited to form a large-capacity memory in this type of semiconductor integrated circuit device, and the channel width of transistors for memory cells is therefore made narrow. In addition, the channel width of transistors for logic devices is made wide to increase the current drive capacity.

If the transistors for memory cells and transistors, for logic devices are configured with the same channel length and the channel injection conditions are made the same in this case, the known reverse narrow channel effect in which threshold voltage Vth decreases as the channel width of transistors decreases causes the threshold voltage Vth of the memory cell transistors to fall below the threshold voltage Vth of the logic device transistors.

If the memory is SRAM, for example, the threshold voltage Vth of the SRAM transistors is preferably high to reduce the standby leak current that flows during standby mode. The ion injection processes must be carried out separately for the channel regions of the SRAM transistors and logic device transistors to raise the threshold voltage Vth of the SRAM transistors, and costs therefore increase as described above.

In a case in which memory is DRAM, moreover, the threshold voltage is preferably set high to suppress the drop in data holding capacity caused by a high leak current. The ion injection process must also be carried out separately for the channel regions of DRAM transistors and logic device transistors in a case in which the threshold voltage of DRAM transistors is set high.

### SUMMARY OF THE INVENTION

It is an object of the present invention to provide a semiconductor integrated circuit device and fabrication method that allow common conditions for ion injection of the channel regions of transistors having different threshold voltages and channel widths, whereby a reduction in the number of photomasks and processing steps can be realized.

To realize the above-described object of the present invention, the threshold voltage of transistors is set by the amount of overlap, which is the amount of overlap between the channel region and source region in the direction of channel length and the amount of overlap between channel region and drain region in the direction of the channel length. By adopting this method, the channel regions of each of a plurality of types of transistors having different threshold voltages or a plurality of types of transistors having equal threshold voltages but different channel widths can be formed at the same time using common photomasks and under the same ion injection conditions.

As a result, the number of photomasks and the number of processing steps can be reduced, thereby reducing the TAT and cost of a semiconductor integrated circuit device in which the above-described plurality of types of transistors are mounted together.

The above and other objects, features, and advantages of the present invention will become apparent from the following description based on the accompanying drawings which illustrate examples of preferred embodiments of the present invention.

### BRIEF DESCRIPTION OF THE DRAWINGS

FIG. 1 is a process chart showing the fabrication procedures of a semiconductor integrated circuit device of the prior art in which transistors having different threshold voltages are mounted together;

FIG. 2 is a process chart showing the fabrication procedures of a semiconductor integrated circuit device of the prior art in which transistors having different threshold voltages are mounted together;

FIG. 3A is a plan view showing the configuration of the first embodiment of the semiconductor integrated circuit device of the present invention;

FIG. 3B is a side sectional view showing the configuration of the first embodiment of the semiconductor integrated circuit device of the present invention;

FIG. 4 is a circuit diagram showing an example of a semiconductor integrated circuit device in which low-threshold transistors and high-threshold transistors are mounted together;

FIG. 5 is a graph showing the relation between channel length and threshold voltage representing an example of the characteristic of the reverse short channel effect;

FIGS. 6A and B are a schematic enlarged side sectional views of a semiconductor integrated circuit device for explaining the mechanism of generating the reverse short channel effect;

FIG. 7 is a graph showing the relation between overlap length and threshold voltage, which shows an example of the reverse short channel effect;

FIG. 8 is a process chart showing the fabrication procedures of the first embodiment of the semiconductor integrated circuit device of the present invention;

FIG. 9 is a process chart showing the fabrication procedures of the first embodiment of the semiconductor integrated circuit device of the present invention;

FIG. 9A is a plan view showing the configuration of the second embodiment of the semiconductor integrated circuit device of the present invention;

FIG. 10B is a side sectional view showing the second embodiment of the semiconductor integrated circuit device of the present invention;

FIG. 11 is a process chart showing the fabrication procedures of the second embodiment of the semiconductor integrated circuit device of the present invention;

FIG. 12 is a process chart showing the fabrication procedures of the second embodiment of the semiconductor integrated circuit device of the present invention.

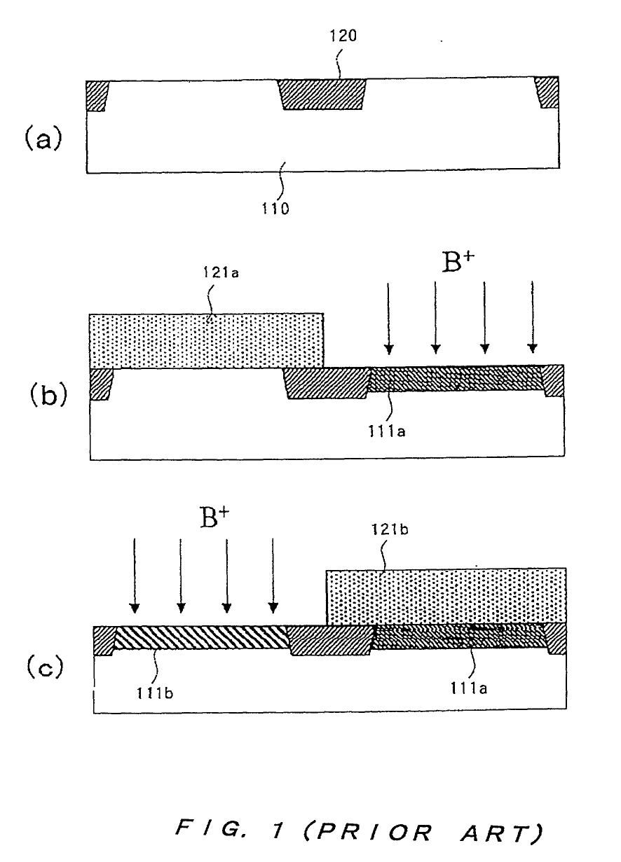

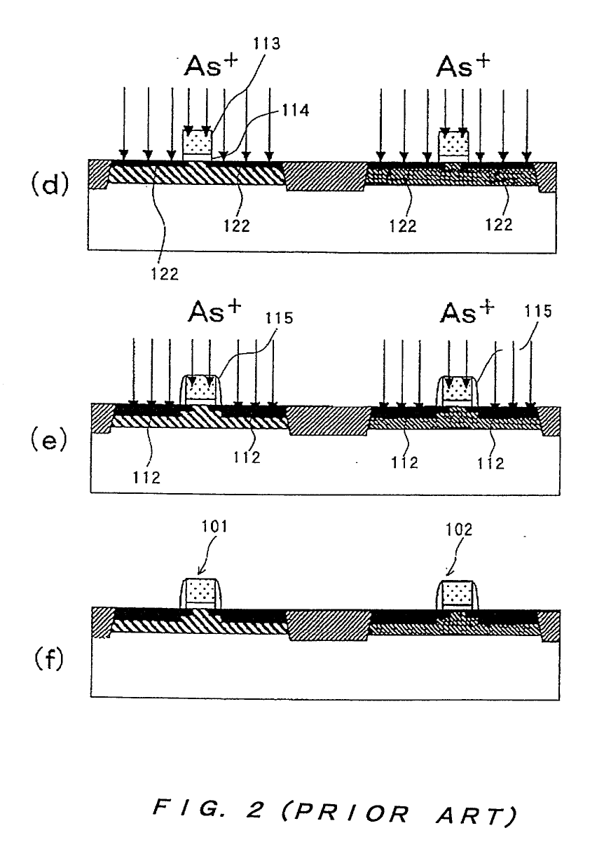

### DETAILED DESCRIPTION OF THE PREFERRED EMBODIMENT

First Embodiment

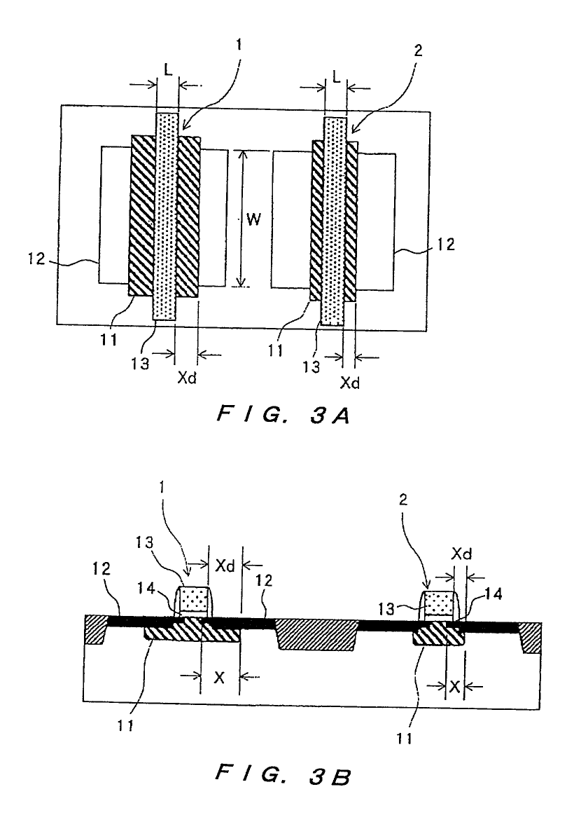

We first refer to FIGS. 3A and 3B, which show the configuration of the semiconductor integrated circuit device of this embodiment. Although channel region 11 is represented as overlying source-drain region 12 in FIG. 3A to clearly show the relation between source-drain regions 12 and channel region 11, channel region 11 is actually formed below source-drain regions 12 as shown in FIG. 3B.

As shown in FIGS. 3A and 3B, the semiconductor integrated circuit device of this embodiment is a construction in which, for a case in which the channel widths and channel lengths of the transistors are the same, transistors having different threshold voltages Vth are formed on the same substrate by varying the amount of overlap X in the direction of channel length between source-drain regions 12 and channel regions 11 of the transistors (hereinbelow referenced to as the “overlap length”).

In concrete terms, low-threshold transistor 1 is formed by lengthening the channel region of the transistors in the direction of channel length and increasing overlap length X, and high-threshold transistor 2 is formed by shortening the channel region of the transistor in the direction of channel length and reducing overlap length X.

The impurity (for example, arsenic) that is injected into source-drain region 12 is very slightly diffused toward the axial direction of gate electrode 13 by an annealing process, and the overlap length that can actually be controlled is length Xd from the end of gate electrode 13 to the end of channel region 11.

One example of application of this embodiment is, for example, a semiconductor integrated circuit device in which a low-speed logic unit and a high-speed logic unit are mounted together; and the threshold voltage of transistors for the low-speed logic unit (low-speed transistors) is raised by shortening the channel region in the direction of channel length and decreasing overlap length X, and the threshold voltage of transistors for the high-speed logic unit (high-speed transistors) is set low by lengthening the channel region in the direction of channel length and increasing overlap length X. By adopting this approach, low-speed transistors and high-speed transistors can be formed on a single chip at the same time without employing different photomasks.

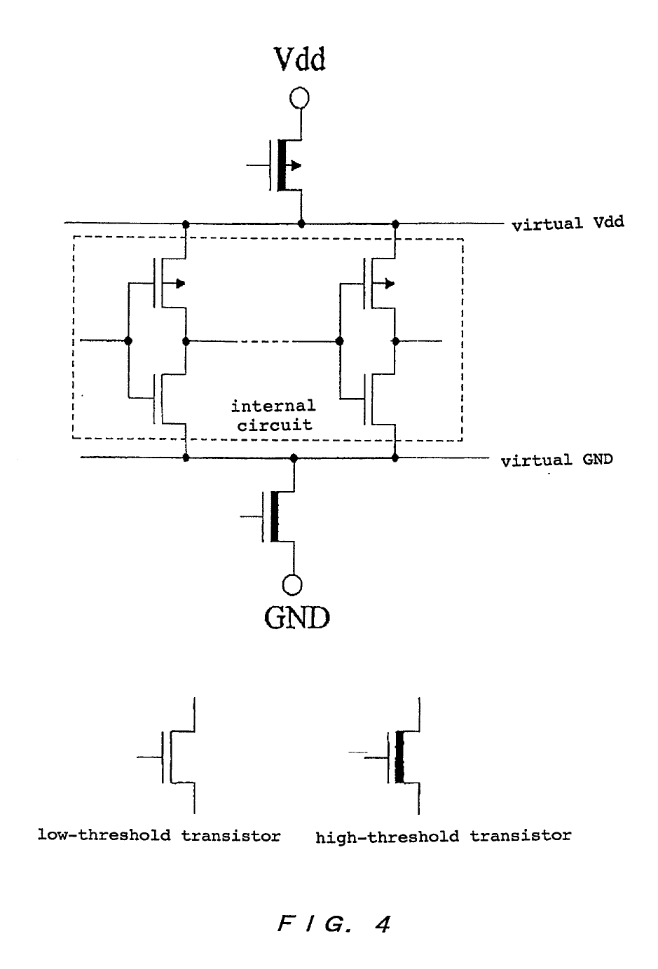

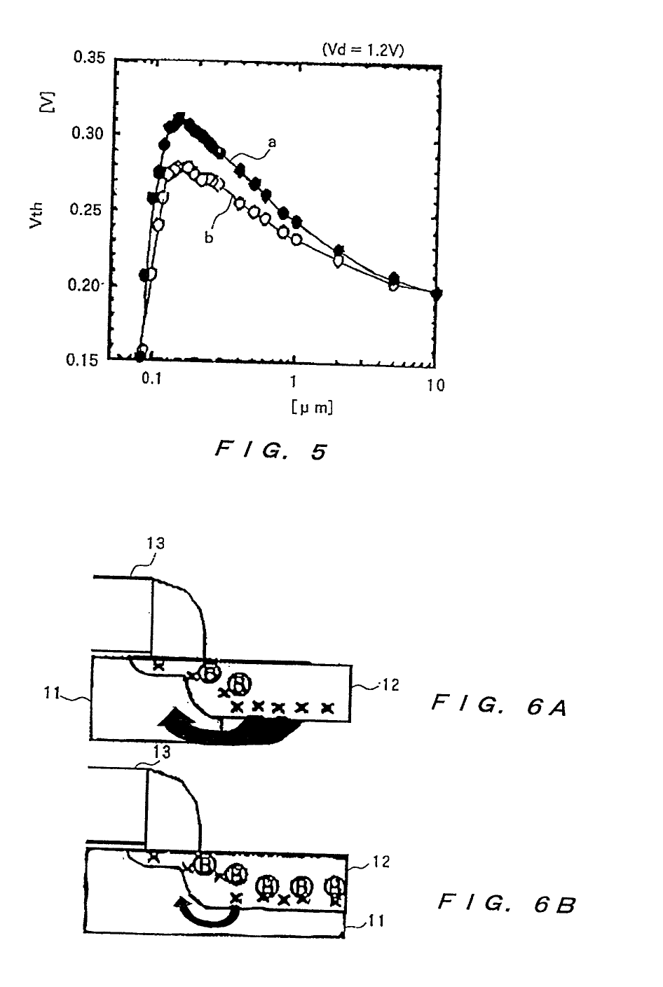

As in the circuit shown in FIG. 4, a configuration can be considered in which internal circuits are constituted using circuit transistors that are made up by low-threshold transistors, and connecting transistors that are constituted by high-threshold transistors are inserted both between the actual power supply Vdd and virtual Vdd line which is the power supply line for the internal circuits and between the actual ground potential GND and virtual ground (virtual GND) line which is the ground potential for the internal circuits.

Although a configuration is shown in FIG. 4 in which connecting transistors are inserted both between the virtual Vdd line and actual power supply Vdd and between the virtual ground (virtual GND) line and the actual ground potential GND, a connecting transistor may also be inserted only between virtual Vdd line and actual power supply Vdd or only between virtual GND line and actual ground potential GND.

Normally, the leak current of a low-threshold transistor is high when OFF and power consumption is therefore high when the transistor is inactive. Accordingly, as shown in FIG. 4, the leak current of the overall circuit during inactivity is reduced by providing connecting transistors (high-threshold transistors) in which the overlap length X is made shorter than in transistors of the internal circuit between power supply Vdd and virtual Vdd (or between ground potential GND and virtual GND) and thus decreasing the leak current when OFF.

The reasons the threshold voltage Vth of a transistor can be controlled by varying overlap length X are next explained using FIGS. 5-7.

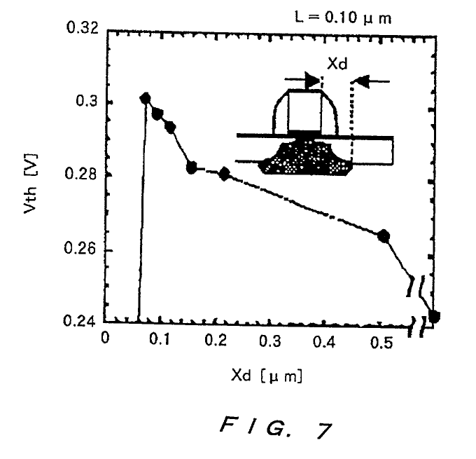

FIG. 5 shows the characteristic of threshold voltage Vth with respect to channel length (gate electrode length) L when drain voltage Vd that is applied across the source and drain is 1.2 V, and FIG. 7 shows the characteristic of threshold voltage Vth with respect to Xd when channel length (gate electrode length) L is 0.1 μm.

It is known that in a semiconductor integrated circuit device that is highly integrated, the threshold voltage typically drops with decrease in the channel length L due to the short channel effect. Recently, however, the existence of a reverse short channel effect has been reported in which the threshold voltage rises with decrease of the channel length L of a transistor (for example, A. Ono et al., 1997 IEDM Technical Digest, pp. 227-230).

The reverse short channel effect is caused by a phenomenon called TED (Transient Enhanced Diffusion) in which interstitials point defects that are generated by injecting arsenic (As), a heavy atom, into the source-drain regions are caused by an annealing process to combine with boron (B) that is injecting into the channel region and thus form BI (Boron/Interstitial) pairs, following which these BI pairs move to the vicinity of the surface of the p-type semiconductor substrate.

BI pairs that are generated at the end of the source-drain (channel side) move to the vicinity of the surface of p-type semiconductor substrate 10, and the concentration of impurity (B) in the vicinity of both ends of the channel therefore increases. Thus, as the channel length L becomes shorter, the proportion of regions in which the impurity concentration is high increases and the threshold voltage Vth rises.

The inventors observed that the characteristic of the reverse short channel effect (threshold voltage Vth with respect to channel length L) can be controlled by varying the above-described overlap length X of channel region 11 and source-drain region 12 of a transistor. In other words, the rise in threshold voltage Vth can be increased by decreasing overlap length X as shown by “a” in FIG. 5; and the rise in threshold voltage Vth can be decreased by increasing overlap length X as shown by “b” in FIG. 5.

As shown in FIG. 6A, when overlap length X is small, interstitials point defects (shown by “X” in FIG. 6) that occur in source-drain region 12 cannot combine with nearby boron (shown by “B” in FIG. 6), move to the end of the source-drain (channel side), and combine with boron there. It is believed that this results in an increase in the number of BI pairs that occur at the ends of the source-drain and that contribute to change in threshold voltage Vth and an increase in the impurity (B) concentration at both ends of the channel, whereby the reverse short channel effect becomes dramatic, and the rise of threshold voltage Vth increases.

When overlap length X is large, on the other hand, the interstitials point defects that occur in source-drain region 12 combine with nearby boron in channel region 11 as shown in FIG. 6B, and there is consequently little increase in the number of BI pairs that are generated at the source-drain ends and that contribute to change in threshold voltage Vth. It is assumed that the rise in threshold voltage Vth is therefore small.

Accordingly, if the threshold voltage of a transistor is set by varying overlap length X within a range of channel length L in which change in threshold voltage Vth is great, transistors having different threshold voltages Vth can be fabricated at the same time using the same mask and under the same ion injection conditions. In other words, the number of masks and the number of processes can be reduced, thereby reducing the cost and TAT of a semiconductor integrated circuit device in which a plurality of types of transistors having different threshold voltages are mounted together.

As described in the foregoing explanation, the overlap length that can actually be controlled is length Xd from the end of gate oxide film 14 and gate electrode 13 as far as the end of channel region 11. As an example, FIG. 7 shows a graph showing how the threshold voltage Vth changes with respect to overlap length Xd.

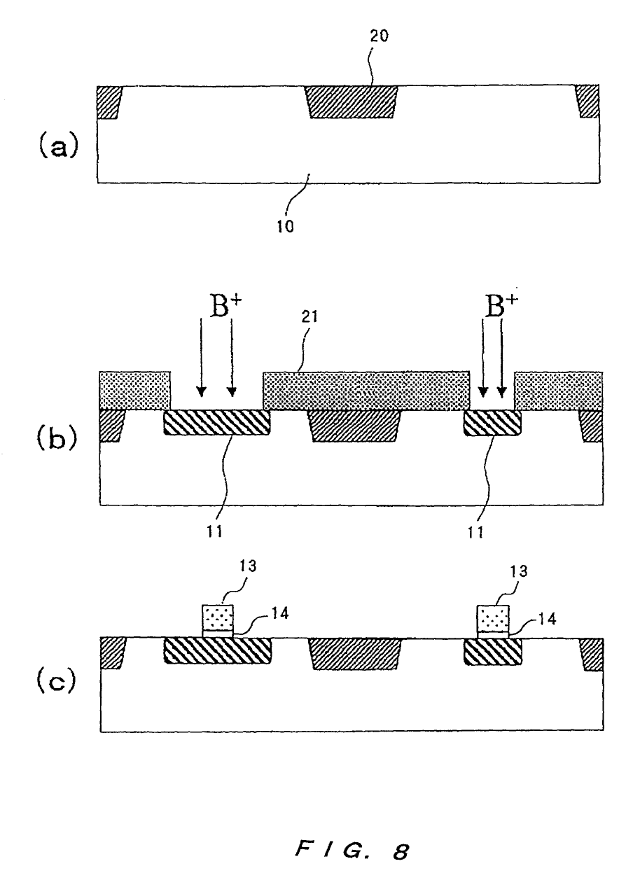

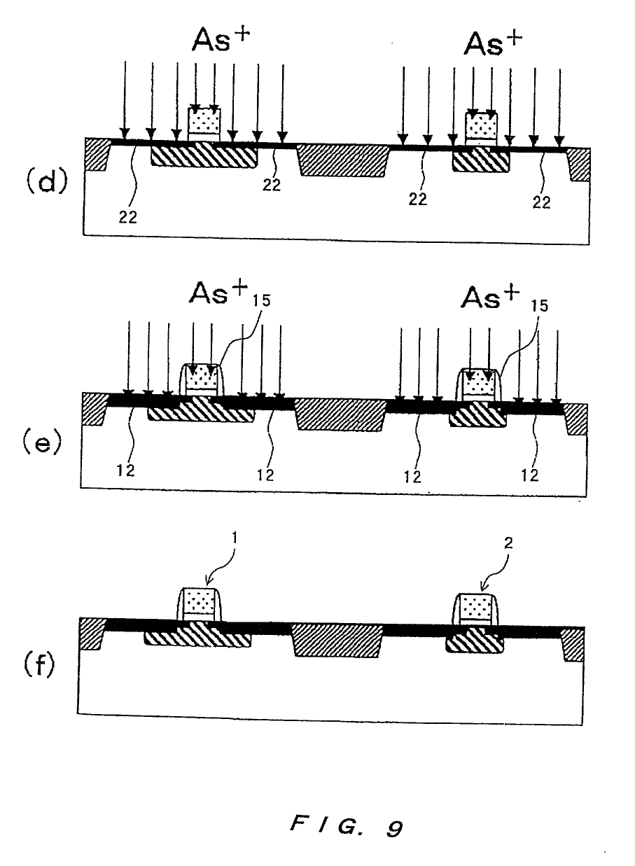

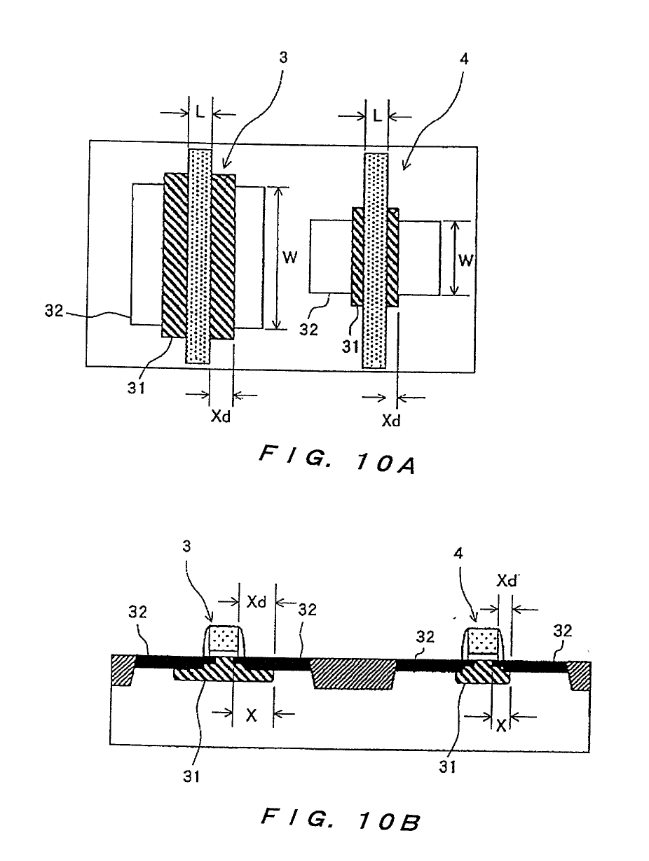

The method of fabricating the semiconductor integrated circuit device of this embodiment is next described using FIGS. 8 and 9. In the following explanation, a case is described in which n-channel FETs of MOS configuration are used as the transistors.

As in the prior art, in the method of fabricating the semiconductor integrated circuit device of this embodiment, p-type semiconductor substrate 10 having a low impurity concentration (for example, 1×10¹⁶ atms/cm³ or less) is first subjected to thermal oxidation to grow a thermal oxide film composed of silicon dioxide (SiO²) and having a thickness of approximately 5 nm, and over this film, a silicon nitride film (Si₃N₄) having a thickness of approximately 150 nm is grown by CVD (Chemical Vapor Deposition). Next, a photoresist is formed on the silicon nitride film, and this photoresist is patterned using photolithography to form an element isolation region for isolating each of the transistors.

Next, the silicon nitride film and thermal oxide film are each removed at the open portions of the photoresist by dry etching, and the vicinity of the surface of p-type semiconductor substrate 10 is removed by etching to form trenches having a depth of, for example, 200-400 nm.

The photoresist on the silicon nitride film is then removed, and an inner-wall oxide film composed of silicon dioxide (SiO₂) and having a thickness of 10-40 nm is grown by thermal oxidation on the bottom and side surfaces of the trenches.

A plasma oxide film composed of silicon dioxide (SiO₂) is then buried in the trenches by, for example, HDP (High-Density Plasma)-CVD, and the upper surface of the plasma oxide film is leveled by CMP (Chemical Mechanical Polishing) to expose the silicon nitride film. The silicon nitride film and thermal oxide film on the p-type semiconductor substrate are further removed by wet etching and element isolation region 20 is formed (FIG. 8(a)).

Next, photoresist 21 is formed on p-type semiconductor substrate 10, and photoresist 21 is patterned using photolithography so as to have openings at the channel regions of low-threshold transistor 1 and high-threshold transistor 2. At this time, patterning is carried out using a photomask such that the opening length of photoresist 21 in the direction of channel length L is greater for low-threshold transistor 1 than for high-threshold transistor 2.

Next, boron (B) is injected through the open portions of photoresist 21 and into the surface of p-type semiconductor substrate 10 under the conditions of, for example, 10-40 keV and 2×10¹²-1.5×10¹³ atms/cm² to form channel regions 11 of each of low-threshold transistor 1 and high-threshold transistor 2 (FIG. 8(b)).

Photoresist 21 on p-type semiconductor substrate 10 is next removed, the surface of p-type semiconductor substrate 10 is subjected to thermal oxidation at a temperature of 700° C.-1000° C. to grow gate oxide film 14 composed of silicon dioxide (SiO₂) and having a thickness of approximately 3 nm (10 nm or less), and a polysilicon film having a thickness of approximately 150 nm (300 nm or less) that is to become the gate electrode is formed on this gate oxide film by a CVD method.

A photoresist is then formed on the polysilicon film, this photoresist is patterned by photolithography to form the gate electrode, and the polysilicon film at the open portions of the photoresist is then removed dry etching to form gate electrode 13 (FIG. 8(c)).

Using gate electrode 13 as a mask, arsenic (As) is then injected into p-type semiconductor substrate 10 under the conditions of, for example, 2 keV (5 keV or less) and 2×10¹⁴-2×10¹⁵ atms/cm² to form SD extension region 22 (FIG. 9(d)).

A dielectric film having a thickness of 200-400 nm and composed of a silicon dioxide film, a silicon nitride film, or a lamination of these films is deposited on p-type semiconductor substrate 10 and gate electrode 13 by a CVD method, and etch-back is carried out by a dry etching method to form side walls 15 on the side surfaces of gate electrode 13.

Using gate electrode 13 and side walls 15 as a mask, arsenic (As) is then injected into p-type semiconductor substrate 10 under the conditions of, for example, 20-40 keV and 2×10¹⁵-1×10¹⁶ atms/cm² to form source-drain region 12 (FIG. 9(e)).

Finally, an RTA (Rapid Thermal Anneal) process is carried under the conditions 900° C.-1100° C. and 60 seconds or less to activate the dopant of each of channel region 11 and source-drain regions 12, thereby completing each of low-threshold transistor 1 and high-threshold transistor 2 (FIG. 9(f)). Wiring is subsequently carried out by a known method for the source and drain using a material such as silicide.

Second Embodiment

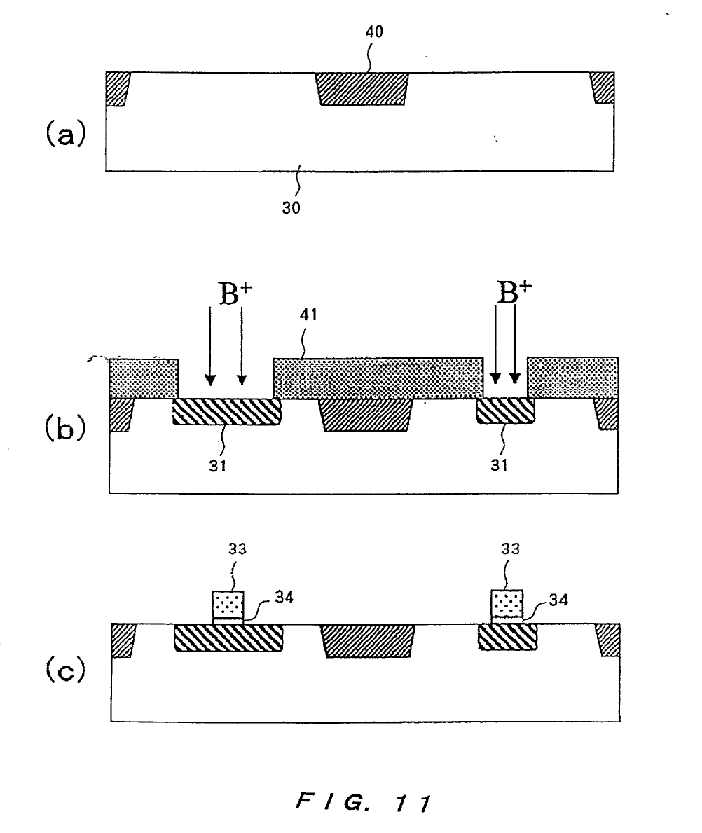

Turning now to FIGS. 10A and 10B, the configuration of the second embodiment of the semiconductor integrated circuit device of this embodiment is explained. Although channel region 31 is represented as overlying source-drain region 32 in FIG. 10A to clearly show the relation between source-drain region 32 and channel region 31, channel region 31 is actually formed below source-drain region 32 as shown in FIG. 10B.

As shown in FIGS. 10A and 10B, the semiconductor integrated circuit device of this embodiment is a construction in which the channel length L of the transistors is common but the channel width W is different, and the threshold voltage Vth of each transistor is set to a desired value by varying the amount of overlap (overlap length X) in the direction of channel length between channel region 31 and source-drain region 32 of the transistors. In concrete terms, the threshold voltage Vth of wide-channel transistor 3, which has a wide channel width W, is set low by increasing the overlap length X; and the threshold voltage Vth of narrow-channel transistor 4, which has a narrow channel width W that is reduced by the reverse narrow channel effect, is set high by decreasing the overlap length X. The threshold voltages Vth of the transistors can be controlled by varying the overlap length X for the same reasons as explained in the first embodiment, and redundant explanation is here omitted.

Thus, by varying the overlap length X between the source-drain region and channel region to set the threshold voltages of the transistors in this way, transistors having the same threshold voltage Vth but differing channel widths W can be fabricated at the same time, using the same masks, and under the same ion injection conditions. Since the number of masks and fabrication steps can be reduced as in the first embodiment, the costs and TAT of the semiconductor integrated circuit device can be reduced.

An example of the application of this embodiment is a semiconductor integrated circuit device in which transistors for logic units (logic transistors) and memory cell transistors such as SRAM (Static Random Access Memory) or DRAM (Dynamic Random Access Memory) are mounted together; wherein the threshold voltage Vth of the memory cell transistors that have a wide channel width W is set high by making the overlap length X small, and the threshold voltage Vth of logic transistors that have a wide channel width W is set low by making the overlap length X large. By adopting this method, memory cell transistors having a small area and moreover, a low leak current, can be fabricated by the same processes as the logic transistors.

In addition to the above-described example of application, a semiconductor integrated circuit device can be considered in which a high-speed logic unit is mounted together with a lower-speed logic unit on a single chip, and the threshold voltage of transistors (high-speed transistors) for use at higher-speed logic than transistors for low-speed logic (low-speed transistors) is set to a lower level. In this case, when the channel width W of the high-speed transistors is set wide to raise the current drive capacity, the threshold voltage Vth of the high-speed transistors, in which channel width W has been widened, is raised by the reverse narrow channel effect.

Here, the conditions for injecting ions into the channel regions are shared for both the low-speed transistors and high-speed transistors, and the overlap length X of the high-speed transistors is made greater than that of the low-speed transistors. By adopting this method, despite increase of the channel width W to raise the current drive capacity, increasing the overlap length X suppresses increase in the threshold voltage and suppresses a decrease in the transistor operating speed.

As yet another example of application, a construction can be considered in which transistors for use in a buffer circuit (for example, a buffer circuit used in an I/O unit or transistors that are used for high-current drive inside a logic circuit) and transistors for use in a logic unit (logic transistors) are mounted together, the threshold voltages of these transistors being substantially equal.

When the channel width W of the transistors for use in the buffer circuit is widened to raise the current drive capacity, the threshold voltage Vth becomes higher due to the reverse narrow channel effect. Accordingly, rise in threshold voltage Vth causes an increase in delay (when ON), and in the interest of suppressing this phenomenon, the overlap length X of the buffer circuit transistor is made greater than that of the logic transistors to set the threshold voltage to a low level.

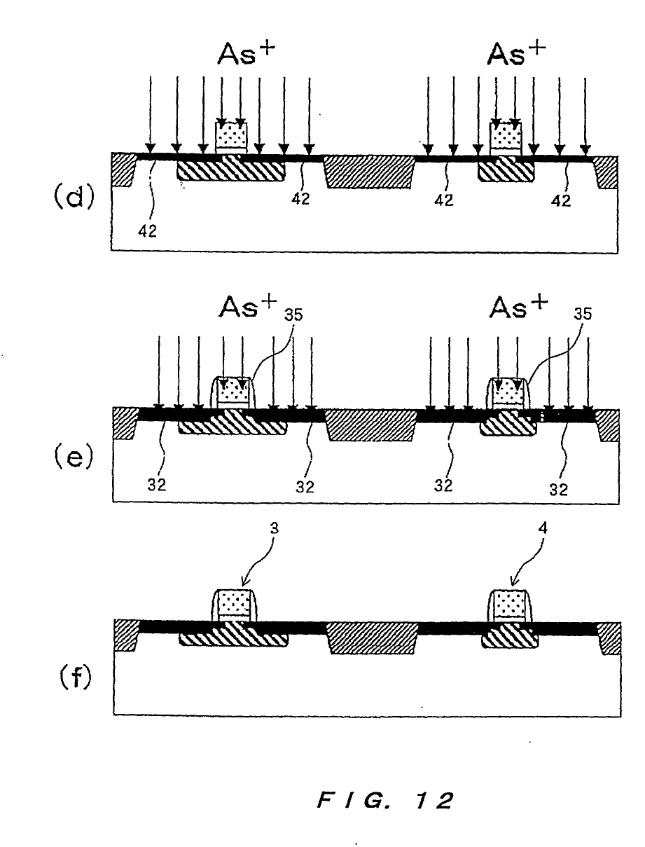

The method of fabricating the semiconductor integrated circuit device of the present embodiment is next explained using FIGS. 11 and 12. In the following explanation, a case is described in which n-channel FETs of MOS configuration are used as the transistors.

As with the prior art, in the method of fabricating a semiconductor integrated circuit device of this embodiment, p-type semiconductor substrate 30 having a low impurity concentration (for example, 1×10¹⁶ atms/cm³ or less) is first subjected to thermal oxidation to form a thermal oxide film composed of silicon dioxide (SiO₂) approximately 5 nm thick, following which a silicon nitride film (Si₃N₄) approximately 150 nm thick is grown over this film by a CVD (Chemical Vapor Deposition) method. A photoresist is next formed on the silicon nitride film, and this photoresist is then patterned using photolithography to form the element isolation region for isolating each transistor.

The silicon nitride film and thermal oxide film at the open portions of the photoresist are next each removed by dry etching, and the vicinity of the surface of the p-type semiconductor substrate is removed by etching to form trenches having a depth of, for example, 200-400 nm.

The photoresist on the silicon nitride film is next removed, and an inner-wall oxide film composed of silicon dioxide (SiO₂) and 10-40 nm thick is grown on the bottom and side surfaces of the trenches by a thermal oxidation method.

A plasma oxide film composed of silicon dioxide (SiO₂) is then embedded in the trenches using an HDP (High-Density Plasma)-CVD method, and the upper surface of the plasma oxide film is leveled by CMP (Chemical Mechanical Polishing) to expose the silicon nitride film. The silicon nitride film and thermal oxide film on the p-type semiconductor substrate are removed by wet etching, and element isolation region 40 composed of field oxide film is formed (FIG. 11(a)).

Photoresist 41 is then formed on p-type semiconductor substrate 30, and photoresist 41 is patterned using photolithography such that the channel regions of wide-channel transistor 3 and narrow-channel transistor 4 have open portions. At this time, patterning is carried out using a photomask such that the length of the openings of photoresist 41 in the direction of channel length is longer in wide-channel transistor 3 than in narrow-channel transistor 4.

Boron (B) is then injected through the open portions of photoresist 41 and into the surface of p-type semiconductor substrate 30 under the conditions of, for example, 10-40 keV and 2×10¹²-1.5×10¹³ atms/cm² to form channel regions 31 of each of wide-channel transistor 3 and narrow-channel transistor 4 (FIG. 11(b)).

Photoresist 41 on p-type semiconductor substrate 30 is next removed, the surface of p-type semiconductor substrate 30 is subjected to thermal oxidation at a temperature of 700° C.-1000° C. to grow gate oxide film 34 composed of silicon dioxide (SiO₂) approximately 3 nm thick (10 nm or less), following which a polysilicon film about 150 nm thick (300 nm or less) that is to become the gate electrode is grown on this gate oxide film 34]by a CVD method.

A photoresist is then grown on the polysilicon film, and after using photolithography to pattern the photoresist for the purpose of forming the gate electrode, the polysilicon film at each of the openings of the photoresist is removed by dry etching to form gate electrode 33 (FIG. 11(c)).

Next, using gate electrode 33 as a mask, arsenic (As) is injected into p-type semiconductor substrate 30 under the conditions of, for example, 2 keV (5 keV or less) and 2×10¹⁴-2×10¹⁵ atms/cm², and SD extension region 42 is formed (FIG. 12(d)).

A dielectric film having a thickness of 200-400 nm and composed of a silicon dioxide film, a silicon nitride film, or a lamination of these films is further deposited on p-type semiconductor substrate 30 and gate electrode 33 by a CVD method and then etched back by dry etching to form side walls 35 on the side surface of gate electrode 33.

Using gate electrode 33 and side walls 35 as a mask, arsenic (As) is next injected into p-type semiconductor substrate 30 under the conditions of, for example, 20-40 keV and 2×10¹⁵-1×10¹⁶ atms/cm² to form source-drain region 32 (FIG. 12(e)).

Finally, an RTA (Rapid Thermal Anneal) process is carried out under the conditions of 900° C.-1100° C. and 60 seconds or less to activate each of the dopants of channel region 31 and source-drain region 32, thereby completing each of wide-channel transistor 3 and narrow-channel transistor 4 (FIG. 12(f)). Wiring of the source and drain is subsequently realized by a known method using, for example, silicide.

Although n-channel FETs of MOS configuration were used as the transistors in the explanations of the above-described first embodiment and second embodiment, the threshold voltage can also be controlled by varying the overlap length X between the channel region and source-drain region in the case of a p-channel FETs.

While preferred embodiments of the present invention have been described using specific terms, such description is for illustrative purposes only, and it is to be understood that changes and variations may be made without departing from the spirit or scope of the following claims.

What is claimed is:

1. A semiconductor integrated circuit device comprising:
a first transistor that is formed on a semiconductor substrate; and
a second transistor that is formed on the same semiconductor substrate as said first transistor, that has the same channel length and channel width as said first transistor, and that has a different amount of overlap than said first transistor, this overlap being the amount of overlap in the direction of said channel length between a channel region and source region and between said channel region and a drain region.

2. The semiconductor integrated circuit device according to claim 1 wherein:
said first transistor is used as a logic circuit; and
said second transistor is used as a high-speed logic circuit that operates at higher speed than said logic circuit and is formed with a greater amount of said overlap than said first transistor.

3. The semiconductor integrated circuit device according to claim 1 wherein:
said first transistor is used as an internal circuit of said semiconductor integrated circuit device, and
said second transistor is used as a connecting transistor that connects said internal circuit and the power supply and is formed with a smaller amount of said overlap than said first transistor.

4. A semiconductor integrated circuit device comprising:
a first transistor that is formed on a semiconductor substrate;
a second transistor that is formed on the same semiconductor substrate as said first transistor, that has the same channel length as said first transistor, and that has different channel width and amount of overlap than said first transistor, this overlap being the amount of overlap in the direction of said channel length between a channel region and source region and between said channel region and a drain region.

5. The semiconductor integrated circuit device according to claim 4 wherein:
said first transistor is used as a logic circuit; and
said second transistor is used as a memory cell in which data are stored and is formed with said channel width that is narrower than said first transistor and said amount of overlap that is smaller than said first transistor.

6. The semiconductor integrated circuit device according to claim 4 wherein:
said first transistor is used as a logic circuit; and
said second transistor is used as a high-speed logic circuit that operates at higher speed than said logic circuit and is formed with said channel width that is broader than in said first transistor and said amount of overlap that is greater than in said first transistor.

7. The semiconductor integrated circuit device according to claim 4 wherein:
said first transistor is used as a logic circuit; and
said second transistor is used as a buffer circuit in which the current drive capacity is higher than that of said first transistor and is formed with said channel width that is greater than said first transistor and said amount of overlap that is greater than in said first transistor.

8. A method of fabricating a semiconductor integrated circuit device wherein the threshold voltage of a transistor is set by controlling the amount of overlap, this amount of overlap being the amount of overlap between a channel region and source region in the direction of channel length and the amount of overlap between said channel region and a drain region in the direction of said channel length.

9. The method of fabricating a semiconductor integrated circuit device according to claim 8 wherein:
a plurality of types of transistor having different said amounts of overlap are formed on the same semiconductor substrate.

10. The method of fabricating a semiconductor integrated circuit device according to claim 8 wherein:
said threshold voltage decreases in proportion to increase in the amount of said overlap.

11. A method of fabricating a semiconductor integrated circuit device for forming a plurality of types of transistor having equal channel lengths and channel widths and having different threshold voltages on the same semiconductor substrate; comprising steps of:
preparing in advance a photomask for forming each of channel regions such that the amount of overlap is larger in a low-threshold transistor, in which said threshold voltage is low, than in a high-threshold transistor, in which said threshold voltage is high; said amount of overlap being the amount of overlap between a channel region and source region in the direction of said channel length and the amount of overlap between said channel region and a drain region in the direction of said channel length;
forming on said semiconductor substrate a photoresist that is patterned using said photomask; and
simultaneously injecting, under the same conditions, prescribed ions into each of the channel region of said low-threshold transistor and the channel region of said high-threshold transistor from openings of said photoresist.

12. A method of fabricating a semiconductor integrated circuit device for forming a plurality of types of transistors having equal channel lengths and different channel widths on the same semiconductor substrate, comprising the steps of:
preparing in advance a photomask for forming each of channel regions such that the amount of overlap is larger in a wide-channel transistor, in which said channel width is wide, than in a narrow-channel transistor, in which said channel width is narrow; said amount of overlap being the amount of overlap between a channel region and source region in the direction of said channel length and the amount of overlap between said channel region and a drain region in the direction of said channel length;
forming on said semiconductor substrate a photoresist that is patterned using said photomask; and
simultaneously injecting, under the same conditions, prescribed ions into each of the channel region of said wide-channel transistor and the channel region of said narrow-channel transistor from openings of said photoresist.
